(19) United States
(12) Patent Application Publication
(10) Pub. No.: US 2024/0348252 A1
(43) Pub. Date: Oct. 17, 2024

(54) Enhanced Adaptive Logic Circuitry with Improved Function Coverage and Packing Ability

(71) Applicants: Jeffrey Chromczak, Toronto (CA); Bee Yee NG, Bayan Lepas (MY); Ilya Ganusov, San Jose, CA (US); Babette Van Antwerpen, Mountain View, CA (US); Grace Zgheib, San Jose, CA (US)

(72) Inventors: Jeffrey Chromczak, Toronto (CA); Bee Yee NG, Bayan Lepas (MY); Ilya Ganusov, San Jose, CA (US); Babette Van Antwerpen, Mountain View, CA (US); Grace Zgheib, San Jose, CA (US)

(21) Appl. No.: 18/756,634

(22) Filed: Jun. 27, 2024

(51) Int. Cl. H03K 19/17728; H03K 19/17736; H03K 19/1776

(52) U.S. Cl. CPC H03K 19/17728; H03K 19/17744; H03K 19/1776

(57) ABSTRACT

To utilize unused or underused input and output pins without a large and undesirable impact on power and die area consumption, an adaptive logic module (ALM) of a programmable logic device may be implemented with an additional 2LUT to improve small function packing density and wide function mapping coverage. The 2LUT may also serve as a route-through to provide direct access to ALM registers with or without input inversion. The enhanced ALM may also use route-through configurations of the additional 2LUT to improve the connectivity of the ALM inputs and outputs.

### BACKGROUND

The present disclosure relates generally to programmable logic devices. More particular, the present disclosure relates to increasing logic density for programmable logic devices (PLDs) such as field programmable gate arrays (FPGAs).

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Programmable logic devices, a class of integrated circuits, may be programmed to perform a wide variety of operations. Some FPGAs include basic building blocks often referred to as adaptive logic modules (ALMs), logic array blocks (LABs), or configurable logic blocks (CLBs). Logic elements such as ALMs or CLBs are programmable logic resources that provide flexibility and reconfigurability in implementing various programmable logic functions. Increasing the quantity of logic elements such as ALMs or CLBs may be advantageous as a greater number of ALMs may enable a greater number of independent functions on an FPGA and may enable wider functions (e.g., functions with a greater number of input pins). A greater number of ALMs may improve overall performance, since enhancing the ability of the FPGA to support wider functions may reduce critical path depth on the FPGA, which may improve data processing and reduce delay. Increasing the quantity of ALMs, however, may consume more power and die area than desirable.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device, in accordance with an embodiment of the present disclosure;

FIG. 2 is a block diagram of the integrated circuit device of FIG. 1, in accordance with an embodiment of the present disclosure;

FIG. 3 is a schematic diagram of an enhanced ALM including an additional two-input LUT (2LUT), in accordance with an embodiment of the present disclosure;

FIG. 4 is a schematic diagram of an enhanced ALM including an additional two-input LUT (2LUT) independently controlled by respective control circuitries, in accordance with an embodiment of the present disclosure;

FIG. 5 is a schematic diagram of an enhanced ALM illustrating a scenario wherein a fracturable 6LUT (e.g., the LUT described with respect to FIGS. 3-4) is fractured into two 5LUTs with shared inputs, in accordance with an embodiment of the present disclosure;

FIG. 6 is a block diagram illustrating an example of different functions that can be packed into an enhanced ALM based on including an additional LUT in the ALM architecture, in accordance with an embodiment of the present disclosure;

FIG. 7 is a block diagram illustrating an example of the different functions that can be packed into an enhanced ALM based on including an additional LUT in the ALM architecture, in accordance with an embodiment of the present disclosure;

FIG. 8 includes a block diagram of the additional LUT implemented as a route-through to improve connectivity and routing flexibility of an enhanced ALM, in accordance with an embodiment of the present disclosure;

FIG. 9 includes a block diagram of the additional LUT implemented as a route-through to improve connectivity and routing flexibility of an enhanced ALM, in accordance with an embodiment of the present disclosure;

FIG. 10, is a diagram illustrating direct ALM inference with respect to the enhanced ALMs, in accordance with an embodiment of the present disclosure;

FIG. 11 is a diagram illustrating independent tech mapping and clustering of LUTs, in accordance with an embodiment of the present disclosure;

FIG. 12 is a flowchart of a method for applying direct inference and/or technology mapping to a plurality of LUTs of an ALM, in accordance with an embodiment of the present disclosure; and

FIG. 13 is an integrated circuit system on which the compiler flow of FIG. 3 may be carried out, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

The present disclosure describes systems and techniques related to increasing logic density of a programmable logic clement or a collection of programmable logic elements implemented in a logic circuit (e.g., an adaptive logic module (ALM) or a configurable logic block (CLB)) of a programmable logic device (PLD) by implementing an additional lookup table (LUT) in an ALM. The additional LUT may leverage unused or underused inputs and improve small function packing density, wider function mapping coverage, and routability.

Some PLD (e.g., FPGA) architectures may be based on a fracturable LUT such as a fracturable 6-input LUT (6LUT). Fracturable LUTs may be desirable as they can be “fractured” or separated into multiple smaller LUTs to provide a greater number of unique functions within an ALM. However, smaller LUTs such as 2-input LUTs (2LUTs) and 3-input LUTs (3LUTs) may consume substantial area of an ALM while making up one-third or less of the number of functions available in a larger LUT, such as a 6LUT. Indeed, only two independent functions may be packed into an ALM having two 2LUTs, although two 2LUTs use only half the input and output routing available in an ALM. As routing consumes a majority of the area of FPGA fabric, such an underutilization of pins may be undesirable. Similar underutilization may be seen in a 6LUT mode, as an ALM having a 6LUT may only use 6 pins out of 8 total pins available. In some 6LUT architectures, the ALM may be unable to pack additional independent logic even though there are input and output pins available. While some ALMs may include an “extended” mode wherein the ALM implements a subset of 7-or 8-input functions, the range of 7-or 8-input functions covered by existing ALM architectures is small and opportunities for use may be rare. In some customer designs only a small percentage of functions map to the extended LUT mode.

To utilize unused or underused input and output pins without a large and undesirable impact on power and die area consumption, an enhanced ALM may be implemented with an additional 2LUT to improve small function packing density and wide function mapping coverage. The 2LUT may also serve as a route-through (also known as a “wire LUT”) to provide direct access to ALM registers with or without input inversion. The enhanced ALM may also use route-through configurations of the additional 2LUT to improve the connectivity of the ALM inputs and outputs.

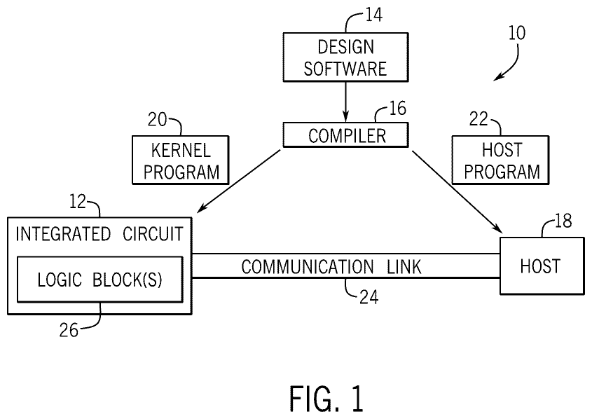

With the foregoing in mind, FIG. 1 illustrates a block diagram of a system 10 that may be used to implement the enhanced ALM of this disclosure on an integrated circuit system 12 (e.g., a single monolithic integrated circuit or a multi-die system of integrated circuits). The integrated circuit system 12 may include a single integrated circuit, multiple integrated circuits in a package, or multiple integrated circuits in multiple packages communicating remotely (e.g., via wires or traces). In some cases, the designer may specify a high-level program to be implemented, such as an OPENCL® program that may enable the designer to more efficiently and easily provide programming instructions to configure a set of programmable logic cells for the integrated circuit system 12 without specific knowledge of low-level hardware description languages (e.g., Verilog, very high-speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit system 12.

In a configuration mode of the integrated circuit system 12, a designer may use an electronic device (e.g., a computer) to implement high-level designs (e.g., a system user design) using design software 14, such as a version of INTEL® QUARTUS® by INTEL CORPORATION. The electronic device 13 may use the design software 14 and a compiler 16 to convert the high-level program into a lower-level description (e.g., a configuration program, a bitstream). The compiler 16 may provide machine-readable instructions representative of the high-level program to a host 18 and the integrated circuit system 12. The host 18 may receive a host program 22 that may control or be implemented by the kernel programs 20. To implement the host program 22, the host 18 may communicate instructions from the host program 22 to the integrated circuit system 12 via a communications link 24 that may include, for example, direct memory access (DMA) communications or peripheral component interconnect express (PCIe) communications. In some embodiments, the kernel programs 20 and the host 18 may configure programmable logic blocks 110 on the integrated circuit system 12. The programmable logic blocks 110 may include circuitry and/or other logic elements and may be configurable to implement a variety of functions in combination with digital signal processing (DSP) blocks 120.

The designer may use the design software 14 to generate and/or to specify a low-level program, such as the low-level hardware description languages described above. Further, in some embodiments, the system 10 may be implemented without a separate host program 22. Thus, embodiments described herein are intended to be illustrative and not limiting.

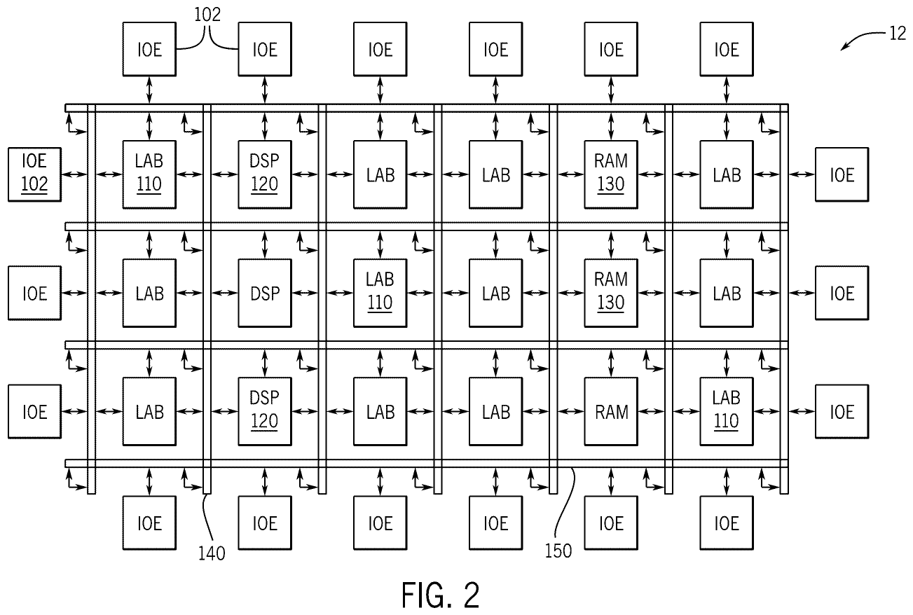

An illustrative embodiment of a programmable integrated circuit system 12 such as a programmable logic device (PLD) that may be configured to implement a circuit design is shown in FIG. 2. As shown in FIG. 2, the integrated circuit system 12 (e.g., a field-programmable gate array integrated circuit) may include a two-dimensional array of functional blocks, including programmable logic blocks 110 (also referred to as logic array blocks (LABs) or configurable logic blocks (CLBs)) and other functional blocks, such as embedded digital signal processing (DSP) blocks 120 and embedded random-access memory (RAM) blocks 130, for example. Functional blocks such as LABs 110 may include smaller programmable regions (e.g., logic elements, configurable logic blocks, or adaptive logic modules) that receive input signals and perform custom functions on the input signals to produce output signals. LABs 110 may also be grouped into larger programmable regions sometimes referred to as logic sectors that are individually managed and configured by corresponding logic sector managers. The grouping of the programmable logic resources on the integrated circuit system 12 into logic sectors, logic array blocks, logic elements, or adaptive logic modules is merely illustrative. In general, the integrated circuit system 12 may include functional logic blocks of any suitable size and type, which may be organized in accordance with any suitable logic resource hierarchy.

Programmable logic in the integrated circuit system 12 may contain programmable memory elements. Memory elements may be loaded with configuration data (also called programming data or configuration bitstream) using input-output elements (IOEs) 102. Once loaded, the memory elements each provide a corresponding static control signal that controls the operation of an associated functional block (e.g., LABs 110, DSP 120, RAM 130, or input-output elements 102).

In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), lookup tables, logic arrays, AND, OR, NAND, and NOR logic gates, pass gates, etc.

The memory elements may use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory, configuration random-access memory (CRAM), or programmable memory elements. The integrated circuit system 12 may be configured to implement a custom circuit design. For example, the configuration RAM may be programmed such that LABs 110, DSP 120, and RAM 130, programmable interconnect circuitry (e.g., vertical routing channels 140 and horizontal routing channels 150), and the input-output elements 102 form the circuit design implementation.

In addition, the programmable logic device may have input-output elements (IOEs) 102 for driving signals off the integrated circuit system 12 and for receiving signals from other devices. Input-output elements 102 may include parallel input-output circuitry, serial data transceiver circuitry, differential receiver and transmitter circuitry, or other circuitry used to connect one integrated circuit to another integrated circuit.

The integrated circuit system 12 may also include programmable interconnect circuitry in the form of vertical routing channels 140 (e.g., interconnects formed along a vertical axis of the integrated circuit system 12) and horizontal routing channels 150 (e.g., interconnects formed along a horizontal axis of the integrated circuit system 12), each routing channel including at least one track to route at least one wire. If desired, the interconnect circuitry may include pipeline elements, and the contents stored in these pipeline elements may be accessed during operation. For example, a programming circuit may provide read and write access to a pipeline element.

Note that other routing topologies, besides the topology of the interconnect circuitry depicted in FIG. 2, are intended to be included within the scope of the present invention. For example, the routing topology may include wires that travel diagonally or that travel horizontally and vertically along different parts of their extent as well as wires that are perpendicular to the device plane in the case of three-dimensional integrated circuits, and the driver of a wire may be located at a different point than one end of a wire. The routing topology may include global wires that span substantially all of the integrated circuit system 12, fractional global wires such as wires that span part of the integrated circuit system 12, staggered wires of a particular length, smaller local wires, or any other suitable interconnection resource arrangement.

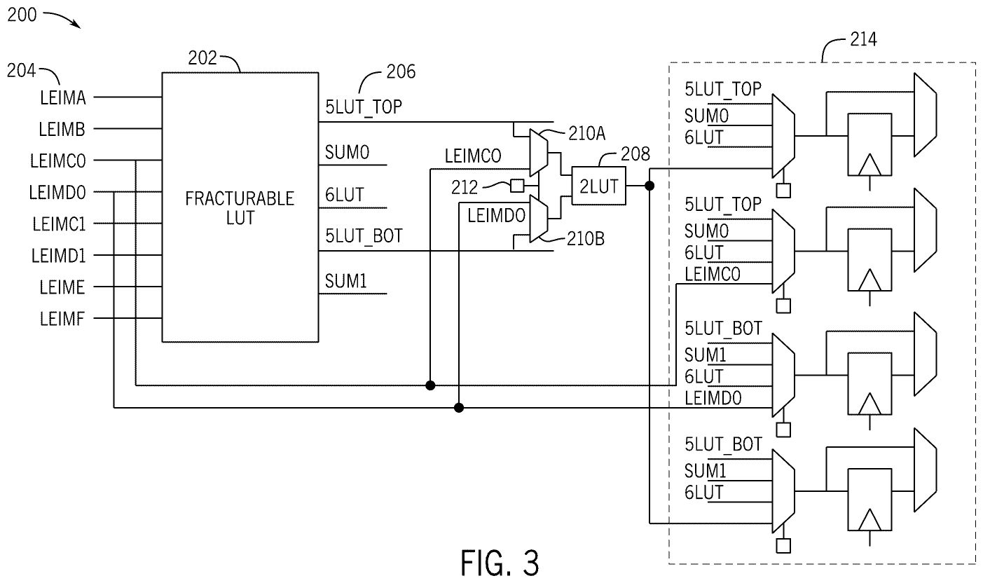

FIG. 3 is a schematic diagram of an enhanced ALM including an additional two-input LUT (2LUT), according to embodiments of the present disclosure. The enhanced ALM 200 includes a fracturable LUT 202 having multiple inputs, such as logic-element input multiplexer (LEIM) inputs 204. While the fracturable LUT 202 is illustrated and described as a fracturable 6LUT having eight inputs, it should be noted that the fracturable LUT 202 may include a LUT of any appropriate size, such as a 5LUT, 4LUT, 3LUT, 2LUT, and so on. The fracturable LUT 202 includes outputs 206. As the fracturable LUT 202 is a fracturable 6LUT, the LUT may function as two 3LUTs, three 2LUTs, two 5LUTs (e.g., with input-sharing), and so on. Accordingly, the outputs of the fracturable LUT 202 may correspond to outputs from any function available in the fracturable LUT 202. For example, the outputs may include a 6LUT output, a 5LUT output, one or more 3LUT outputs, one or more 2LUT outputs, and so on.

As previously discussed, some ALMs may have unused or underutilized inputs, such as the LEIMC0 input and the LEIMD0 input. As the routing consumes the majority of the die area on a programmable logic device (e.g., an FPGA), the unused or underutilized input pins may be undesirable. To utilize these input pins and improve ALM performance, an additional LUT 208 (e.g., a 2LUT) may be implemented in the enhanced ALM 200. While the additional LUT 208 is illustrated as a 2LUT, it should be noted that any appropriately sized LUT may be implemented as an additional LUT in the enhanced ALM 200. For example, the additional LUT 208 may include a 3LUT, a 4LUT, and so on, depending on the die area available in the ALM, the number of pins available, and so on. The enhanced ALM 200 may also include multiplexers 210A and 210B (the multiplexers 210) electrically coupled to the additional LUT 208. Inputs of the multiplexers 210 may be coupled (e.g., directly) to inputs and/or outputs of the fracturable LUT 202. Outputs of the multiplexers 210 may be coupled (e.g., directly) to respective inputs of the additional LUT 208 to control the inputs of the additional LUT 208 and thus control the type of function performed by the additional LUT 208. Selection circuitry 212 coupled to enable inputs of the multiplexers 210 may output a selection signal (e.g., a configuration bit) to control whether the inputs to (e.g., the LEIMC0 and LEIMD0) or outputs of (e.g., 5LUT_TOP or 5LUT_BOT) the fracturable LUT 202 are selected as inputs to the additional LUT 208 in a given clock cycle. It should be noted that the selection circuitry 212 can cause the multiplexers 210A and 210B to select the outputs of the fracturable LUT 202 (e.g., in a fully-cascaded scenario). The selection circuitry 212 may also cause the multiplexers 210A and 210B to select the inputs LEIMC0 and LEIMD0, respectively (e.g., in a non-cascaded scenario). The selection circuitry 212 may also cause one multiplexer 210 to select an input and one multiplexer 210 to select an output. For example, the selection circuitry 212 may output a configuration bit to the multiplexer 210A, causing the multiplexer 210A to select the input LEIMC0 as output to the additional LUT 208 and may output another configuration bit to the multiplexer 210B, causing the multiplexer 210B to select the output of the fracturable LUT 202 (e.g., 5LUT_BOT) to output to the additional LUT 208.

If coupled to inputs 204 of the fracturable LUT 202, the additional LUT 208 may perform additional independent functions. Moreover, if coupled to unused inputs 204, the independent functions provided by the additional LUT 208 may be purely additive. If coupled to outputs of the fracturable LUT 202, the additional LUT 208 may enable cascaded functions within the enhanced ALM 200. Routing circuitry 214 may include multiplexers and registers, and may receive input signals from the inputs 204 of the fracturable LUT 202, output signals from the outputs 206 of the fracturable LUT 202, outputs from the additional LUT 208, or any combination thereof. In this manner, the enhanced ALM 200 may benefit from the additional LUT 208, which may utilize unused or underused input pins of the fracturable LUT 202 to provide greater logic density and wider function mapping with minimal impact on power and die area consumption.

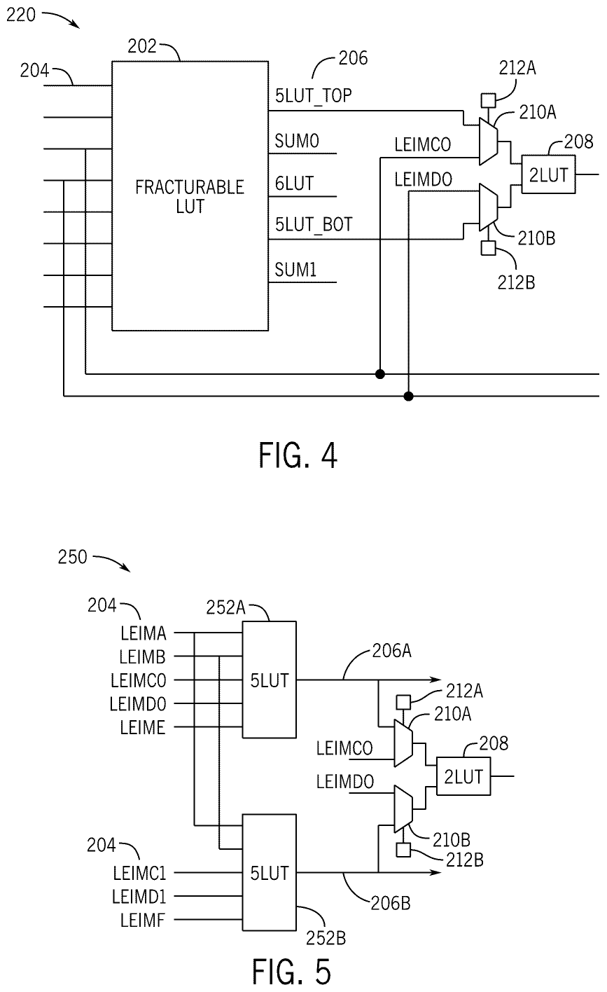

FIG. 4 is a schematic diagram of an enhanced ALM 220 including an additional two-input LUT (2LUT) independently controlled by respective control circuitries 212A and 212B, according to embodiments of the present disclosure. The enhanced ALM 220 may operate similarly to the enhanced ALM 200, except that control circuitry 212A and 212B enable the multiplexers 210A and 210B to select either inputs or outputs of the fracturable LUT 202 independently of each other. For example, the multiplexer 210A may select the fracturable LUT 202 output 5LUT top as the input to the additional LUT 208 while the multiplexer 210B may select the fracturable LUT 202 input LEIMD0 as the input to the additional LUT 208.

FIG. 5 is a schematic diagram of an enhanced ALM 250 illustrating a scenario wherein a fracturable 6LUT (e.g., the fracturable LUT 202 described with respect to FIGS. 3-4) is fractured into two 5LUTs 252A and 252B (collectively, the 5LUTs 252) with shared inputs, according to embodiments of the present disclosure. As may be appreciated, as a fracturable 6LUT has 8 inputs, some inputs 204 may be shared between the 5LUT 252A and the 5LUT 252B to provide 5 inputs to each. For example, the 5LUT 252A may utilize the input pins LEIMA, LEIMB, LEIMC0, LEIMD0, and LEIME, while the 5LUT 525B may share the input pins LEIMA and LEIMB with the 5LUT 252A and utilize the unshared input pins LEIMC1, LEIMD1, and LEIMF. The multiplexer 210A may receive as inputs the output of the 5LUT 252A and the input LEIMC0. The multiplexer 210B may receive as inputs the output of the 5LUT 252B and the input LEIMD0.

In each clock cycle, the additional LUT 208 of the enhanced ALM 250 may receive as inputs an output 206A of the 5LUT 252A or the input LEIMC0 and an output 206B of the 5LUT 252B or the input LEIMD0. For example, in a fully cascaded mode, the multiplexer 210A may select the output 206A and the multiplexer 210B may select the output 206B as inputs to the additional 2LUT 208.

In a semi-cascaded mode, the multiplexer 210A may select the output 206A as input to the additional 2LUT 208 and the multiplexer 210B may select the input LEIMD0 as input to the additional 2LUT 208. In another example, the multiplexer 210A may select the input LEIMC0 as input to the additional 2LUT 208 and the multiplexer 210B may select the output 206B as input to the additional 2LUT 208.

In a non-cascaded mode, the multiplexer 210A may select the input LEIMC0 as input to the additional 2LUT 208 and the multiplexer 210B may select the input LEIMD0 as input to the additional 2LUT 208, such that neither of the outputs 206A and 206B (collectively the outputs 206) may be taken as inputs to the additional 2LUT 208.

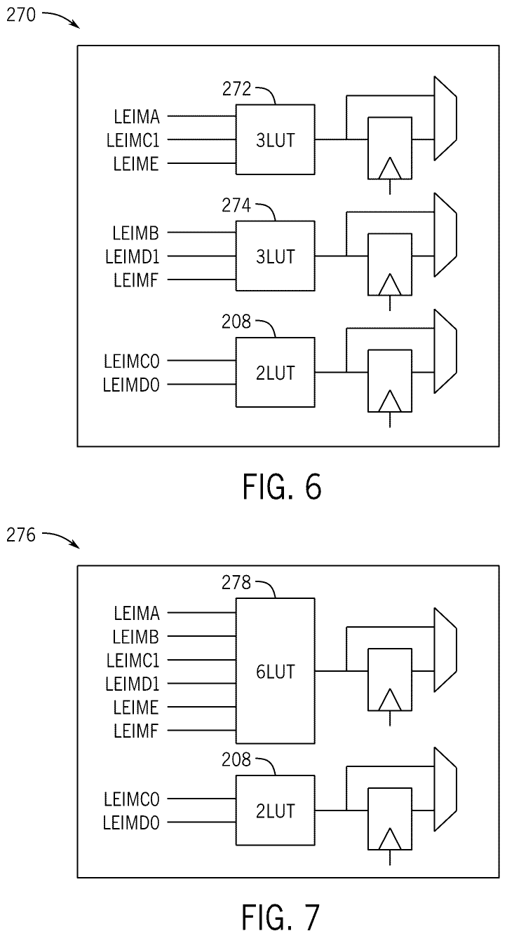

While two 5LUTs are illustrated and described with respect to FIG. 5, it should be noted that this is merely illustrative, and a fracturable LUT may be fractured into any appropriate combination of LUTs, such as two 4LUTs, two 3LUTs, three 2LUTs, and so on. With this in mind, FIG. 6 is a block diagram illustrating an example of the different functions that can be packed into an enhanced ALM based on including an additional LUT 208 in the ALM architecture, according to embodiments of the present disclosure. An enhanced ALM 270 may support three functions. The first function and the second function are provided by 3LUT 272 and 3LUT 274. It should be noted that the 3LUT 272 and the 3LUT 274 may each include a respective portion of a fracturable LUT (e.g., the fracturable LUT 202), such as a fracturable 6LUT. The additional LUT 208 may provide additional logic functionality beyond the capability of the 3LUTs 272 and 274. As shown with respect to the enhanced ALM 270, the additional LUT 208 may utilize inputs that are unused by the 3LUTs 272 and 274 (e.g., LEIMC0 and LEIMD0), such that the 3LUT 272, the 3LUT 274, and the additional LUT 208 share no inputs and the additional LUT 208 is not cascaded (e.g., the additional LUT 208 does not receive, as inputs, outputs from the 3LUT 272 or the 3LUT 274). However, this is merely illustrative and, as previously discussed, the inputs of the additional LUT 208 may include shared inputs from the 3LUT 272 and/or the 3LUT 274, or may include outputs from the 3LUT 272 and/or the 3LUT 274 to produce cascading functions within the first enhanced ALM 270, or may take as inputs a combination of shared inputs, non-shared inputs, and/or outputs from the 3LUT 272 and/or the 3LUT 274.

FIG. 7 is a block diagram illustrating an example of the different functions that can be packed into an enhanced ALM based on including an additional LUT 208 in the ALM architecture, according to embodiments of the present disclosure. An enhanced ALM 276 may support two functions: the first function provided by a 6LUT 278 and the second function provided by the additional LUT 208. The additional LUT 208 may provide additional logic functionality beyond the capability of the 6LUT. As may be observed, the additional LUT 208 may utilize inputs that are unused by the 6LUT 276 (e.g., LEIMC0 and LEIMD0), such that the 6LUT 278 and the additional LUT 208 share no inputs and the additional LUT 208 is not cascaded (e.g., the additional LUT 208 does not receive outputs from the 6LUT 278). However, this is merely illustrative and, as previously discussed, the inputs of the additional LUT 208 may share the inputs of the 6LUT 278 (e.g., may receive signals from the LEIMA, LEIMB, LEIMC1, LEIMD1, LEIME and/or LEIMF inputs), may take in as inputs the output of the 6LUT 278 to produce cascading functions, or may take as inputs a combination of shared inputs, non-shared inputs, and/or outputs from the 6LUT 278.

The additional 2LUT 208 may be implemented as a route-through to improve the connectivity and routing flexibility of the ALM. In certain ALMs, individual inputs (e.g., LEIMC0/1, LEIMD0/1 inputs) may be hardwired to the packed input of each ALM register. In an embodiment of the presently described enhanced ALMs, the additional LUT 208 may be configured to pass inputs (e.g., LEIMC0/1, LEIMD0/1) to one or more registers, providing greater routing flexibility. The additional LUT 208 may also add an input inversion, providing an additional benefit that may not be feasible with other packed register architectures.

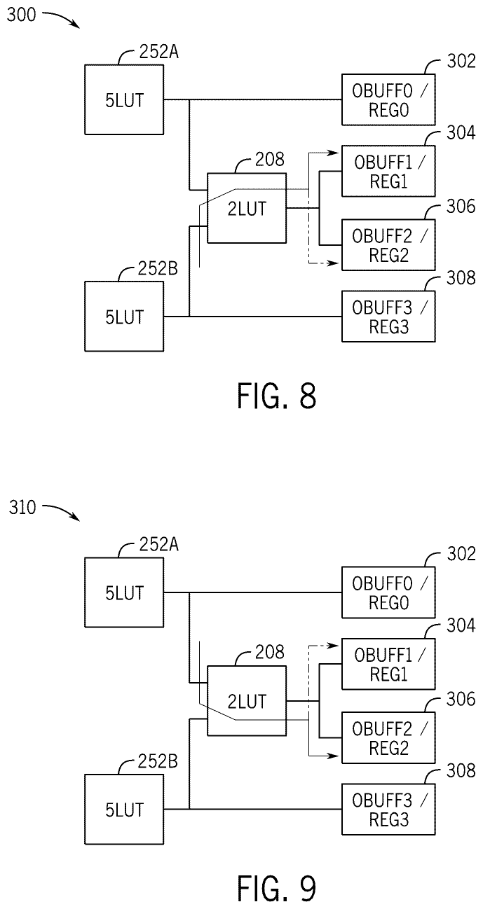

With this in mind, FIG. 8 includes a block diagram of the additional LUT 208 implemented as a route-through to improve connectivity and routing flexibility of an enhanced ALM, according to embodiments of the present disclosure. An enhanced ALM 300 may include the 5LUTs 252A and 252B and the additional LUT 208 as described with respect to FIG. 5. The enhanced ALM 300 also includes buffers/registers 302, 304, 306, and 308. The additional LUT 208 may receive an output (or input, as discussed with respect to FIGS. 3-5) from the 5LUT 252B and route it to one or more buffers or registers, such as the buffer/register 304 and/or the buffer/register 306. This may be advantageous as, in some ALMs, the 5LUTS 252A and 252B may have been hardwired to the buffers or registers, such that, for example, the 5LUT 252B may have only been able to output to the buffers/registers 306 and 308. However, as may be appreciated from the enhanced ALM 300, the 5LUT 252B may now output to the buffers/registers 304, 306, and/or 308.

Similarly, FIG. 9 includes a block diagram of the additional LUT 208 implemented as a route-through to improve connectivity and routing flexibility of an enhanced ALM 310, according to embodiments of the present disclosure. Looking to the enhanced ALM 310, the 5LUT 252A may output to the additional LUT 208 such that the additional LUT 208 may route the output to the buffer/register 304 and/or the buffer/register 306. As discussed above with respect to FIG. 8, this may be advantageous as, in some ALM implementations, the 5LUT 252A may have been hardwired to the buffers/registers 302 and 304, and may have been unable to output to any other buffer. However, leveraging the additional LUT 208 as a route-through, the 5LUT 252A may be able to output to the buffer/register 302, 304, and/or 306. In this manner, the additional LUT 208 may improve connectivity and routing flexibility of the enhanced ALMs 300 and 310. It should be noted that the enhanced ALM 300 described with respect to FIG. 8 and the enhanced ALM 310 described with respect to FIG. 9 may be the same ALM, and are merely illustrated as two portions to show routing from the 5LUT 252A and the 5LUT 252B, respectively. It should also be noted that the enhanced ALMs 300 and 310 may include any type of LUT, such as any LUT or combination of LUTs that may be generated from a fracturable 6LUT. It should also be noted that the outputs of the 5LUTs 252A and 252B may be actual outputs of the 5LUTs 252 themselves (such that the outputs are cascaded) or the outputs may actually be inputs that are routed to the additional 2LUT 208, as described with respect to FIGS. 3-5.

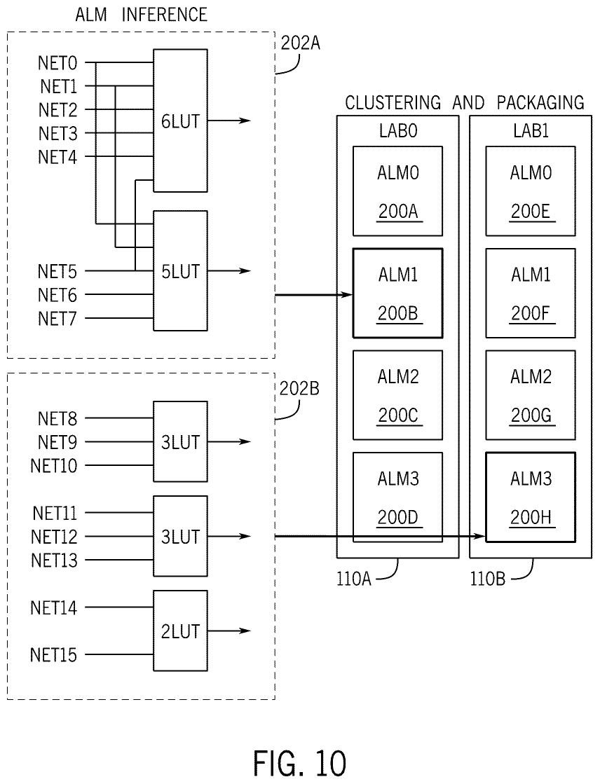

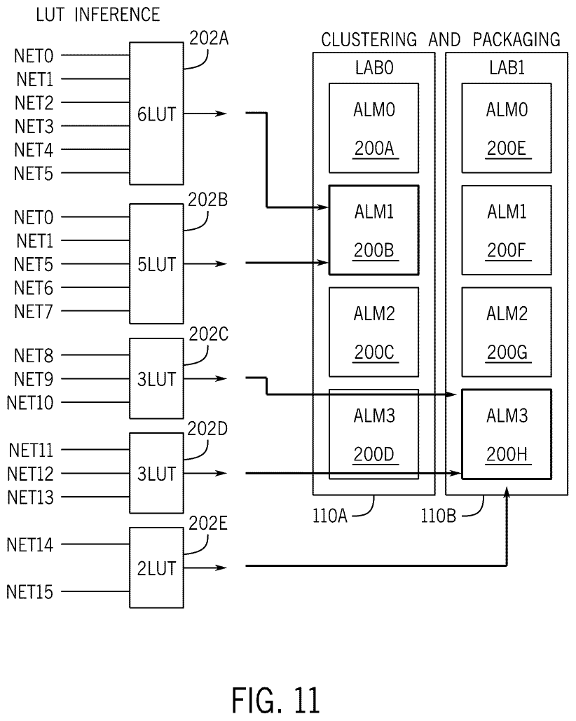

FIG. 10 is a diagram illustrating direct ALM inference with respect to the enhanced ALMs discussed above, according to embodiments of the present disclosure. A LAB 110A may include ALMs (e.g., enhanced ALMs) 200A, 200B, 200C, and 200D. A LAB 100B may include ALMs (e.g., enhanced ALMs) 200E, 200F, 200G, and 200H. A LUT 202A may include a fracturable 6LUT that may be fractured into a 6LUT and a 5LUT, as illustrated. An inference algorithm and a technology mapping algorithm may identify the fracturable LUT 202A (including the 6LUT and 5LUT) as ALM-level logic cuts that may fit into one ALM and may include multiple functions (e.g., the functions provided by the 6LUT and the functions provided by the 5LUT). The tech mapping may include clustering the fracturable LUT 202A into an appropriate ALM (e.g., 202B) for operation in the LAB 110A. Likewise, a LUT 202B may include a fracturable 6LUT that may be fractured into two 3LUTs and may be combined with an additional 2LUT (e.g., the additional LUT 208), as illustrated. Inference and tech mapping may identify the fracturable LUT 202B (including the two 3LUTs and the 2LUT) as ALM-level logic cuts that may fit into one ALM and may include multiple functions (e.g., the functions provided by the two 3LUTs and the 2LUT). The tech mapping may include the fracturable LUT 202B into an appropriate ALM (e.g., 202H) for operation in the LAB 110B. The LUTs 202A and 202B may include the fracturable LUT 202 discussed above as well as the additional LUT 208 as previously discussed. FIG. 11 is a diagram illustrating independent tech mapping and clustering of LUTs, according to embodiments of the present disclosure. FIG. 11 includes LUTs 202A, 202B, 202C, 202D, and 202E (collectively, the LUTs 202). Each of the LUTs 202 may be tech mapped independently and clustered (e.g., via a clustering algorithm) in a different (e.g., later) stage of an FPGA compiler flow. For example, after tech mapping, the LUTs 202A and 202B may be clustered in the ALM 200B of the LAB 110A and the LUTs 202C, 202D, and 202E may be clustered in the ALM 200H of the LAB 110B. A hybrid approach may be implemented in some embodiments, such that certain ALM modes with complex input sharing may be inferred directly (e.g., as described with respect to FIG. 10) while other LUTs are tech mapped and clustered in different stages of the FPGA compiler flow.

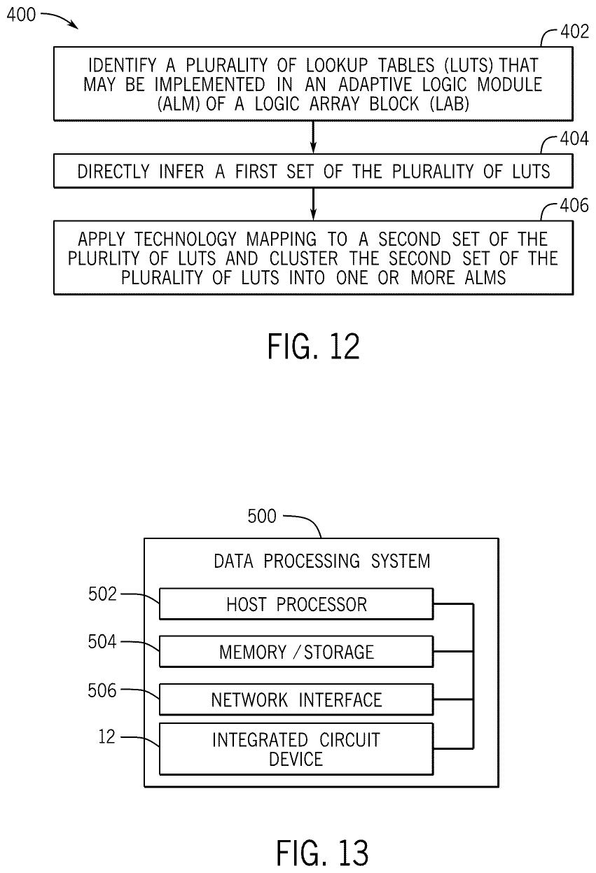

FIG. 12 is a flowchart of a method 400 for applying direct inference and/or technology mapping to a plurality of LUTs of an ALM, according to embodiments of the present disclosure. As discussed above, LUTs may be implemented into an ALM via multiple processes, such as direct inference, independent technology mapping and clustering, or a combination thereof. In process block 402, the compiler 16 may identify a plurality of LUTs that may be implemented in logic circuitry such as an ALM or other logic element of a LAB 110 or a CLB. The compiler 16 may, in process block 404, directly infer (e.g., via an inference algorithm) a first set of the plurality of LUTs. In process block 406, the compiler 16 may apply technology mapping to a second set of the plurality of LUTs and cluster the second set of the plurality of LUTs into one or more ALMs. In this manner, the method 400 enables a hybrid approach to be implemented such that certain ALM modes (e.g., modes with complex input sharing) may be inferred directly while other LUTs are tech mapped and clustered in different stages of the FPGA compiler flow.

The processes discussed above may be carried out on the integrated circuit system 12, which may be a component included in a data processing system, such as a data processing system 500, shown in FIG. 13. The data processing system 500 may include the integrated circuit system 12 (e.g., a programmable logic device), a host processor 502, memory and/or storage circuitry 504, and a network interface 506. The data processing system 500 may include more or fewer components (e.g., electronic display, user interface structures, application specific integrated circuits (ASICs)). The host processor 502 may include any of the foregoing processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 504 may include random access memory (RAM), read-only memory (ROM), one or more hard drives, flash memory, or the like. The memory and/or storage circuitry 504 may hold data to be processed by the data processing system 500. In some cases, the memory and/or storage circuitry 504 may also store configuration programs (e.g., bitstreams, mapping function) for programming the integrated circuit system 12. The network interface 506 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as cities, states, or countries.

The data processing system 500 may be part of a data center that processes a variety of different requests. For instance, the data processing system 500 may receive a data processing request via the network interface 506 to perform encryption, decryption, machine learning, video processing, voice recognition, image recognition, data compression, database search ranking, bioinformatics, network security pattern identification, spatial navigation, digital signal processing, or other specialized tasks.

The techniques and methods described herein may be applied with other types of integrated circuit systems. For example, the programmable routing bridge described herein may be used with central processing units (CPUs), graphics cards, hard drives, or other components.

While the embodiments set forth in the present disclosure may be susceptible to various modifications and alternative forms, specific embodiments have been shown by way of example in the drawings and have been described in detail herein. However, the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

EXAMPLE EMBODIMENT 1. Logic circuitry comprising:
a first lookup table (LUT) configurable to receive as inputs a set of inputs into the logic circuitry and output a set of outputs; and
a second LUT configurable to selectively receive as inputs:
   one or more of the set of inputs into the logic circuitry; and
   one or more of the set of outputs.

EXAMPLE EMBODIMENT 2. The logic circuitry of example embodiment 1, wherein the first LUT comprises a 6-input fracturable LUT.

EXAMPLE EMBODIMENT 3. The logic circuitry of example embodiment 2, wherein the second LUT comprises a 2-input LUT.

EXAMPLE EMBODIMENT 4. The logic circuitry of example embodiment 3, wherein the first LUT and the second LUT are configurable to operate as two-function logic circuitry utilizing 8 logic inputs.

EXAMPLE EMBODIMENT 5. The logic circuitry of example embodiment 3, wherein the first LUT and the second LUT are configurable to operate as three-function logic circuitry utilizing 8 logic inputs.

EXAMPLE EMBODIMENT 6. The logic circuitry of example embodiment 1, wherein a fifth output of the second LUT is coupled to a first memory buffer and a second memory buffer.

EXAMPLE EMBODIMENT 7. The logic circuitry of example embodiment 6, wherein the fifth output is configured to route an input signal to the first memory buffer or the second memory buffer.

EXAMPLE EMBODIMENT 8. The logic circuitry of example embodiment 1, wherein the first multiplexer and the second multiplexer are coupled to shared enable circuitry, the shared enable circuitry configured to output a first configuration bit to select the first multiplexer or a second configuration bit to select the second multiplexer.

EXAMPLE EMBODIMENT 9. The logic circuitry of example embodiment 1, wherein the first multiplexer is coupled to first enable circuitry and the second multiplexer is coupled to second enable circuitry.

EXAMPLE EMBODIMENT 10. A method comprising:
identifying a plurality of lookup tables (LUT) that may be implemented in an adaptive logic module (ALM) of a logic array block (LAB), the plurality of LUTs comprising:
   a first LUT configurable to receive as inputs a set of inputs and output a set of outputs; and
   a second LUT coupled to one or more inputs of the set of inputs and one or more outputs of the set of outputs;
directly inferring a first set of the plurality of LUTs; and
applying technology mapping to a second set of the plurality of LUTs and clustering the second set of the plurality of LUTs into one or more ALMs.

EXAMPLE EMBODIMENT 11. The method of example embodiment 10, wherein the first set of the plurality of LUTs, the second set of the plurality of LUTs, or both comprise a fracturable LUT and an additional LUT coupled to an output of the fracturable LUT.

EXAMPLE EMBODIMENT 12. The method of example embodiment 11, wherein the fracturable LUT comprises a 6-input fracturable LUT.

EXAMPLE EMBODIMENT 13. Logic circuitry comprising:
a first lookup table (LUT) configurable to provide a first LUT function and a second LUT function;
a second LUT comprising:
   a first input coupled to a first output of the first LUT function of the first LUT;
   a second input coupled to a second output of the second LUT function of the first LUT; and
   an output coupled to a first memory buffer and a second memory buffer, wherein the second LUT is configured to route a first input signal from the first LUT function to the first memory buffer, the second memory buffer, or both.

EXAMPLE EMBODIMENT 14. The logic circuitry of example embodiment 13, wherein the second LUT is configured to route a second input signal from the second LUT function to the first memory buffer, the second memory buffer, or both.

EXAMPLE EMBODIMENT 15. The logic circuitry of example embodiment 13, wherein the first LUT comprises a 6-input fracturable LUT configurable to fracture to provide the first LUT function and the second LUT function.

EXAMPLE EMBODIMENT 16. The logic circuitry of example embodiment 15, wherein the first LUT function, the second LUT function, or both comprise a 5-input LUTs.

EXAMPLE EMBODIMENT 17. The logic circuitry of example embodiment 13, wherein the second LUT comprises a 2-input LUT.

EXAMPLE EMBODIMENT 18. The logic circuitry of example embodiment 13, comprising:
a first multiplexer coupled to a first input of the first LUT, a first output of the first LUT, or both; and
a second multiplexer coupled to a second input of the first LUT, a second output of the first LUT, or both.

EXAMPLE EMBODIMENT 19. The logic circuitry of example embodiment 18, wherein the first multiplexer and the second multiplexer are coupled to shared enable circuitry configured to output a first configuration bit to select the first multiplexer or a second configuration bit to select the second multiplexer.

EXAMPLE EMBODIMENT 20. The logic circuitry of example embodiment 18, wherein the first multiplexer is coupled to first enable circuitry configured to output a first configuration bit to cause the first multiplexer to output to the second LUT and wherein the second multiplexer is coupled to second enable circuitry configured to output a second configuration bit to cause the second multiplexer to output to the second LUT.

What is claimed is:

1. Logic circuitry comprising:
a first lookup table (LUT) configurable to receive as inputs a set of inputs into the logic circuitry and output a set of outputs; and
a second LUT configurable to selectively receive as inputs:
one or more of the set of inputs into the logic circuitry; and
one or more of the set of outputs.

2. The logic circuitry of claim 1, wherein the first LUT comprises a 6-input fracturable LUT.

3. The logic circuitry of claim 2, wherein the second LUT comprises a 2-input LUT.

4. The logic circuitry of claim 3, wherein the first LUT and the second LUT are configurable to operate as two-function logic circuitry utilizing 8 logic inputs.

5. The logic circuitry of claim 3, wherein the first LUT and the second LUT are configurable to operate as three-function logic circuitry utilizing 8 logic inputs.

6. The logic circuitry of claim 1, wherein the second LUT comprises an output coupled to a first memory buffer and a second memory buffer.

7. The logic circuitry of claim 6, wherein the output of the second LUT is configurable to route an input signal to the first memory buffer or the second memory buffer.

8. The logic circuitry of claim 1, wherein the second LUT is configurable to selectively receive a first input of the set of inputs and a first output of the set of outputs via a first multiplexer and configurable to selectively receive a second input of the set of inputs and a second output of the set of outputs via a second multiplexer.

9. The logic circuitry of claim 8, wherein the first multiplexer is coupled to first enable circuitry and the second multiplexer is coupled to second enable circuitry.

10. A method comprising:
identifying a plurality of lookup tables (LUTs) that may be implemented in an adaptive logic module (ALM) of a logic array block (LAB), the plurality of LUTs comprising:
a first LUT configurable to receive as inputs a set of inputs and output a set of outputs; and
a second LUT coupled to one or more inputs of the set of inputs and one or more outputs of the set of outputs;
directly inferring a first set of the plurality of LUTs; and
applying technology mapping to a second set of the plurality of LUTs and clustering the second set of the plurality of LUTs into one or more ALMs.

11. The method of claim 10, wherein the first LUT comprises a 6-input fracturable LUT.

12. The method of claim 10, wherein the second LUT is configurable to selectively receive a first input of the set of inputs and a first output of the set of outputs via a first multiplexer and configurable to selectively receive a second input of the set of inputs and a second output of the set of outputs via a second multiplexer.

13. Logic circuitry comprising:
a first lookup table (LUT) configurable to provide a first LUT function and a second LUT function;
a second LUT comprising:
a first input configurable to receive a first signal associated with the first LUT function of the first LUT;
a second input configurable to receive a second signal associated with the second LUT function of the first LUT; and
an output coupled to a first memory buffer and a second memory buffer, wherein the second LUT is configurable to route a first input signal from the first LUT function to the first memory buffer, the second memory buffer, or both.

14. The logic circuitry of claim 13, wherein the second LUT is configurable to route a second input signal from the second LUT function to the first memory buffer, the second memory buffer, or both.

15. The logic circuitry of claim 13, wherein the first LUT comprises a 6-input fracturable LUT configurable to fracture to provide the first LUT function and the second LUT function.

16. The logic circuitry of claim 15, wherein the first LUT function, the second LUT function, or both comprise a 5-input LUTs.

17. The logic circuitry of claim 13, wherein the second LUT comprises a 2-input LUT.

18. The logic circuitry of claim 13, comprising:
a first multiplexer coupled to a first input of the first LUT, a first output of the first LUT, or both; and
a second multiplexer coupled to a second input of the first LUT, a second output of the first LUT, or both.

19. The logic circuitry of claim 18, wherein the first multiplexer and the second multiplexer are coupled to shared enable circuitry configurable to output a first configuration bit to select the first input of the first LUT or the first output of the first LUT and a second configuration bit to select the second input of the first LUT or the second output of the first LUT.

20. The logic circuitry of claim 18, wherein the first multiplexer is coupled to first enable circuitry configurable to output a first configuration bit to cause the first multiplexer to output to the second LUT and wherein the second multiplexer is coupled to second enable circuitry configurable to output a second configuration bit to cause the second multiplexer to output to the second LUT.
